(19) United States
(12) Patent Application Publication
(10) Pub. No.: US 2025/0029834 A1
(43) Pub. Date: Jan. 23, 2025

(54) METHODS FOR DEPOSITING A MOLYBDENUM METAL FILM ON A DIELECTRIC SURFACE OF A SUBSTRATE AND RELATED SEMICONDUCTOR DEVICE STRUCTURES

(71) Applicant: ASM IP Holding B.V., Almere (NL)

(72) Inventors: Bhushan Zope, Phoenix, AZ (US); Shankar Swaminathan, Phoenix, AZ (US); Kiran Shrestha, Phoenix, AZ (US); Chiyu Zhu, Helsinki (FI); Henri Jussila, Espoo (FI); Qi Xie, Leuven (BE)

(21) Appl. No.: 18/908,990

(22) Filed: Oct. 8, 2024

Related U.S. Application Data
(62) Division of application No. 16/105,745, filed on Aug. 20, 2018, now abandoned.
Application No. 16/105,745 is a continuation-in-part of application No. 15/691,241, filed on Aug. 30, 2017, now Pat. No. 11,056,344.
(60) Provisional application No. 62/607,070, filed on Dec. 18, 2017.
(60) Provisional application No. 62/619,579, filed on Jan. 19, 2018.

(51) Int. Cl. H01L 21/02; H01L 21/768

(52) U.S. Cl. CPC H01L 21/02521; H01L 21/0228; H01L 21/0259; H01L 21/76877

(57) ABSTRACT

Methods for depositing a molybdenum metal film directly on a dielectric material surface of a substrate by a cyclical deposition process are disclosed. The methods may include: providing a substrate comprising a dielectric surface into a reaction chamber; and depositing a molybdenum metal film directly on the dielectric surface, wherein depositing comprises: contacting the substrate with a first vapor phase reactant comprising a molybdenum halide precursor; and contacting the substrate with a second vapor phase reactant comprising a reducing agent precursor. Semiconductor device structures including a molybdenum metal film disposed directly on a surface of a dielectric material deposited by the methods of the disclosure are also disclosed.

### CROSS-REFERENCE TO RELATED APPLICATION

This application is a divisional of, and claims priority to and the benefit of, U.S. patent application Ser. No. 16/105,745, filed Aug. 20, 2018 and entitled “METHODS FOR DEPOSITING A MOLYBDENUM METAL FILM ON A DIELECTRIC SURFACE OF A SUBSTRATE AND RELATED SEMICONDUCTOR DEVICE STRUCTURES,” which is a continuation-in-part of U.S. Non-Provisional patent application Ser. No. 15/691,241, filed on Aug. 30, 2017 and entitled “LAYER FORMING METHOD,” now U.S. Pat. No. 11,056,344 issued on Jul. 6, 2021, and also claims priority to and the benefit of U.S. Provisional Patent Application No. 62/607,070, filed on Dec. 18, 2017 and entitled “LAYER FORMING METHOD” and U.S. Provisional Patent Application No. 62/619,579, filed on Jan. 19, 2018 and entitled “DEPOSITION METHOD,” all of which are hereby incorporated by reference herein.

### FIELD OF INVENTION

The present disclosure relates generally to methods for depositing a molybdenum metal film on a dielectric material surface of a substrate and particular methods for depositing a molybdenum metal film directly on a surface of a dielectric material by a cyclical deposition process. The present disclosure also general relates to semiconductor device structures including a molybdenum metal film disposed directly on the surface of a dielectric material.

### BACKGROUND OF THE DISCLOSURE

Semiconductor device fabrication processes in advanced technology nodes generally require state of the art deposition methods for forming metal films, such as, for example, tungsten metal films and copper metal films.

A common requisite for the deposition of a metal film is that the deposition process is extremely conformal. For example, conformal deposition is often required in order to uniformly deposit a metal film over three-dimensional structures including high aspect ratio features. Another common requirement for the deposition of metal films is that the deposition process is capable of depositing ultra-thin films which are continuous over a large substrate area. In the particular case wherein the metal film is electrically conductive, the deposition process may need to be optimized to produce low electrical resistivity films.

Low electrical resistivity metal films commonly utilized in state of the art semiconductor device applications may include tungsten (W) and/or copper (Cu). However, tungsten metal films and copper metal films commonly require a thick barrier layer, disposed between the metal film and a dielectric material. The thick barrier layer may be utilized to prevent diffusion of metal species into the underlying dielectric material thereby improving device reliability and device yield. However, the thick barrier layer commonly exhibits a high electrical resistivity and therefore results in an increase in the overall electrical resistivity of the semiconductor device structure.

Cyclical deposition processes, such as, for example, atomic layer deposition (ALD) and cyclical chemical vapor deposition (CCVD), sequential introduce one or more precursors (reactants) into a reaction chamber wherein the precursors react with the surface of the substrate one at a time in a sequential manner. Cyclical deposition processes have been demonstrated which produce metal films with excellent conformality with atomic level thickness control.

Accordingly, methods and related semiconductor device structures are desirable for depositing and utilizing low electrical resistivity metal films which are deposited by a conformal cyclical deposition process.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, methods for depositing a molybdenum metal film on a dielectric material surface of a substrate by a cyclical deposition process are provided. The method may comprise: providing a substrate comprising a dielectric surface into a reaction chamber; and depositing a molybdenum metal film directly on the dielectric surface, wherein depositing comprises: contacting the substrate with a first vapor phase reactant comprising a molybdenum halide precursor; and contacting the substrate with a second vapor phase reactant comprising a reducing agent precursor.

In some embodiments, semiconductor device structures are provided. The semiconductor device structure may comprise: a substrate comprising one or more gap features, wherein the one or more gap features comprise a surface of a dielectric material; and a molybdenum metal film disposed in and filling the one or more gap features, wherein the molybdenum metal film is disposed in direct contact with the surface of the dielectric material.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a non-limiting exemplary process flow, demonstrating an atomic layer deposition process for depositing a molybdenum metal film directly on a dielectric surface according to the embodiments of the disclosure;

FIG. 2 illustrates a non-limiting exemplary process flow, demonstrating a cyclical chemical vapor deposition process for depositing a molybdenum metal film directly on a dielectric surface according to the embodiments of the disclosure;

FIG. 3 illustrates x-ray diffraction (XRD) data obtained from a molybdenum metal film deposited directly on a dielectric surface according to the embodiments of the disclosure; and

FIGS. 4A and 4B illustrate cross-sectional schematic diagrams of semiconductor device structures that includes a molybdenum metal film disposed directly on a dielectric surface according the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed.

As used herein, the term “cyclic deposition” may refer to the sequential introduction of one or more precursors (reactants) into a reaction chamber to deposit a film over a substrate and includes deposition techniques such as atomic layer deposition and cyclical chemical vapor deposition.

As used herein, the term “cyclical chemical vapor deposition” may refer to any process wherein a substrate is sequentially exposed to one or more volatile precursors, which react and/or decompose on a substrate to produce a desired deposition.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film” and “thin film” may refer to any continuous or non-continuous structures and material formed by the methods disclosed herein. For example, “film” and “thin film” could include 2D materials, nanolaminates, nanorods, nanotubes, or nanoparticles, or even partial or full molecular layers, or partial or full atomic layers or clusters of atoms and/or molecules. “Film” and “thin film” may comprise material or a layer with pinholes, but still be at least partially continuous.

As used herein, the term “molybdenum halide precursor” may refer to reactant which comprises at least a molybdenum component and a halide component, wherein the halide component may include one or more of a chlorine component, an iodine component, or a bromine component.

As used herein, the term “molybdenum chalcogenide halide” may refer to a reactant which comprises at least a molybdenum component, a halide component, and a chalcogen component, wherein a chalcogen is an element from group IV of the periodic table including oxygen (O), sulphur(S), selenium (Se), and tellurium (Te).

As used herein, the term “molybdenum oxyhalide” may refer to a reactant which comprises at least a molybdenum component, an oxygen component, and a halide component.

As used herein, the term “reducing agent precursor” may refer to a reactant that donates an electron to another species in a redox chemical reaction.

As used herein, the term “crystalline film” may refer to a film which displays at least short range ordering or even long range ordering of the crystalline structure and includes single crystalline films as well as polycrystalline films.

As used herein, the term “gap feature” may refer to an opening or cavity disposed between two surfaces of a non-planar surface. The term “gap feature” may refer to an opening or cavity disposed between opposing inclined sidewalls of two protrusions extending vertically from the surface of the substrate or opposing inclined sidewalls of an indentation extending vertically into the surface of the substrate, such a gap feature may be referred to as a “vertical gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.”

As used herein, the term “seam” may refer to a line or one or more voids formed by the abutment of edges formed in a gap fill metal, and the “seam” can be confirmed using a scanning transmission electron microscopy (STEM) or transmission electron microscopy (TEM) wherein if observations reveal a clear vertical line or one or more vertical voids in a vertical gap fill metal, or a clear horizontal line or one or more horizontal voids in a horizontal gap fill metal, then a “seam” is present. A number of example materials are given throughout the embodiments of the current disclosure; it should be noted that the chemical formulas given for each of the example materials should not be construed as limiting and that the non-limiting example materials given should not be limited by a given example stoichiometry.

The present disclosure includes methods for depositing a molybdenum metal film directly on a surface of a dielectric material, i.e., without the need for any intermediate layer(s). Molybdenum metal thin films may be utilized in a number of applications, such as, for example, low electrical resistivity gap-fill, liner layers for 3D-NAND, DRAM word-line features, or as an interconnect material in CMOS logic applications. The ability to deposit a molybdenum metal film directly on a dielectric surface may remove the need for an intermediate layer(s) between the dielectric material and the molybdenum metal film, which may allow for lower effective electrical resistivity for interconnects in logic applications, i.e., CMOS structures, and word-line/bit-line in memory applications, such as 3D-NAND and DRAM structures.

Therefore, the embodiments of the disclosure may include methods for depositing a molybdenum metal film directly on a dielectric surface of a substrate by a cyclical deposition process. The methods may comprise: providing a substrate comprising a dielectric material surface into a reaction chamber; and depositing a molybdenum metal film directly on the dielectric surface, wherein depositing comprises: contacting the substrate with a first vapor phase reactant comprising a molybdenum halide precursor; and contacting the substrate with a second vapor phase reactant comprising a reducing agent precursor.

The methods of depositing a molybdenum metal film directly on a dielectric surface of a substrate disclosed herein may comprise a cyclical deposition process, such as, for example, atomic layer deposition (ALD), or cyclical chemical vapor deposition (CCVD).

A non-limiting example embodiment of a cyclical deposition process may include atomic layer deposition (ALD), wherein ALD is based on typically self-limiting reactions, whereby sequential and alternating pulses of reactants are used to deposit about one atomic (or molecular) monolayer of material per deposition cycle. The deposition conditions and precursors are typically selected to provide self-saturating reactions, such that an absorbed layer of one reactant leaves a surface termination that is non-reactive with the gas phase reactants of the same reactants. The substrate is subsequently contacted with a different reactant that reacts with the previous termination to enable continued deposition. Thus, each cycle of alternated pulses typically leaves no more than about one monolayer of the desired material. However, as mentioned above, the skilled artisan will recognize that in one or more ALD cycles more than one monolayer of material may be deposited, for example, if some gas phase reactions occur despite the alternating nature of the process.

In an ALD-type process utilized for the formation of a molybdenum metal film directly on a dielectric surface one deposition cycle may comprise exposing the substrate to a first vapor phase reactant, removing any unreacted first reactant and reaction byproducts from the reaction chamber, and exposing the substrate to a second vapor phase reactant, followed by a second removal step. In some embodiments of the disclosure, the first vapor phase reactant may comprise a molybdenum precursor and the second vapor phase reactant may comprise a reducing agent precursor.

Precursors may be separated by inert gases, such as argon (Ar) or nitrogen (N₂), to prevent gas-phase reactions between reactants and enable self-saturating surface reactions. In some embodiments, however, the substrate may be moved to separately contact a first vapor phase reactant and a second vapor phase reactant. Because the reactions self-saturate, strict temperature control of the substrates and precise dosage control of the precursors may not be required. However, the substrate temperature is preferably such that an incident gas species does not condense into monolayers nor decompose on the surface. Surplus chemicals and reaction byproducts, if any, are removed from the substrate surface, such as by purging the reaction space or by moving the substrate, before the substrate is contacted with the next reactive chemical. Undesired gaseous molecules can be effectively expelled from a reaction space with the help of an inert purging gas. A vacuum pump may be used to assist in the purging.

Reactors capable of being used to deposit molybdenum metal films directly on a dielectric material surface can be used for the cyclical deposition processes described herein. Such reactors include ALD reactors, as well as CVD reactors, configured to provide the precursors. According to some embodiments, a showerhead reactor may be used. According to some embodiments, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers. In some embodiments in which a batch reactor is used, wafer-to-wafer non-uniformity is less than 3% (1 sigma), less than 2%, less than 1%, or even less than 0.5%.

The exemplary cyclical deposition processes described herein may optionally be carried out in a reactor or reaction chamber connected to a cluster tool. In a cluster tool, because each reaction chamber is dedicated to one type of process, the temperature of the reaction chamber in each module can be kept constant, which improves the throughput compared to a reactor in which the substrate is heated up to the process temperature before each run. Additionally, in a cluster tool it is possible to reduce the time to pump the reaction chamber to the desired process pressure levels between substrates. In some embodiments of the disclosure, the exemplary cyclical deposition processes for the deposition of a molybdenum metal film directly on a dielectric surface disclosed herein may be performed in a cluster tool comprising multiple reaction chambers, wherein each individual reaction chamber may be utilized to expose the substrate to an individual precursor gas and the substrate may be transferred between different reaction chambers for exposure to multiple precursors gases, the transfer of the substrate being performed under a controlled ambient to prevent oxidation/contamination of the substrate. In some embodiments of the disclosure, the cyclical deposition processes for the deposition of a molybdenum metal film directly on a dielectric surface may be performed in a cluster tool comprising multiple reaction chambers, wherein each individual reaction chamber may be configured to heat the substrate to a different temperature.

A stand-alone reactor may be equipped with a load-lock. In that case, it is not necessary to cool down the reaction chamber between each run.

According to some non-limiting embodiments of the disclosure, ALD processes may be used to deposit a molybdenum metal film directly on a dielectric material surface. In some embodiments of the disclosure, each ALD cycle may comprise two distinct deposition steps or stages. In a first stage of the deposition cycle (“the molybdenum stage”), the substrate surface on which deposition is desired may be contacted with a first vapor phase reactant comprising a molybdenum precursor which chemisorbs on to the surface of the substrate, forming no more than about one monolayer of reactant species on the surface of the substrate. In a second stage of the deposition the substrate surface on which deposition is desired may be contacted with a second vapor phase reactant comprising a reducing agent precursor (“the reducing stage”).

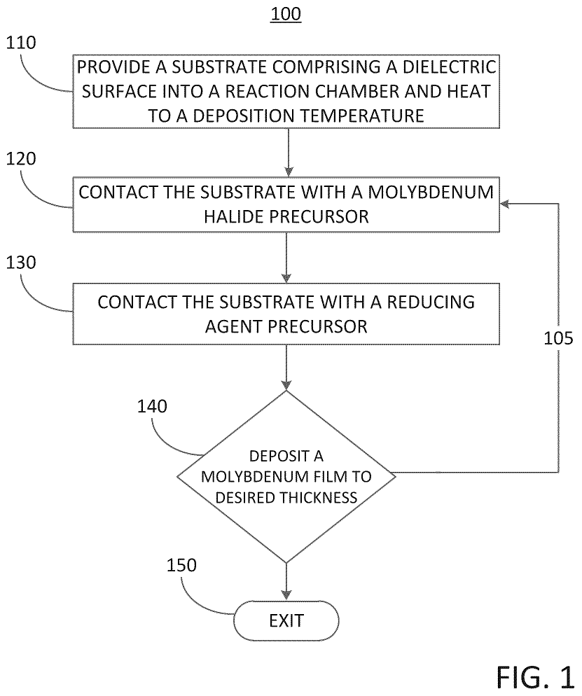

An exemplary atomic layer deposition process for depositing a molybdenum metal film directly on a dielectric material surface may be understood with reference to FIG. 1 which illustrates the exemplary atomic layer deposition process 100 for the deposition of a molybdenum metal film directly on a dielectric surface.

In more detail, FIG. 1 illustrates an exemplary molybdenum deposition process 100 including a cyclical deposition phase 105. The exemplary atomic layer deposition process 100 may commence with a process block 110 which comprises providing a substrate comprising a dielectric surface into a reaction chamber and heating the substrate to a desired deposition temperature.

In some embodiments of the disclosure, the substrate may comprise a planar substrate or a patterned substrate including high aspect ratio features, such as, for example, trench structures, vertical gap features, horizontal gap features, and/or fin structures. The substrate may comprise one or more materials including, but not limited to, semiconductor materials, dielectric materials, and metallic materials.

In some embodiments, the substrate may include semiconductor materials, such as, but not limited to, silicon (Si), germanium (Ge), germanium tin (GeSn), silicon germanium (SiGe), silicon germanium tin (SiGeSn), silicon carbide (SiC), or a group III-V semiconductor material.

In some embodiments, the substrate may include dielectric materials, such as, but not limited, to silicon containing dielectric materials and metal oxide dielectric materials. In some embodiments, the substrate may comprise one or more dielectric surfaces comprising a silicon containing dielectric material such as, but not limited to, silicon dioxide (SiO₂), silicon sub-oxides, silicon nitride (Si₃N₄), silicon oxynitride (SiON), silicon oxycarbide (SiOC), silicon oxycarbide nitride (SiOCN), silicon carbon nitride (SiCN). In some embodiments, the substrate may comprise one or more dielectric surfaces comprising a metal oxide such as, but not limited to, aluminum oxide (Al₂O₃), hafnium oxide (HfO₂), tantalum oxide (Ta₂O₅), zirconium oxide (ZrO₂), titanium oxide (TiO₂), hafnium silicate (HfSiOₓ), and lanthanum oxide (La₂O₃).

In some embodiments of the disclosure, the substrate may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise for example, one or more of silicon (Si), silicon germanium (SiGe), germanium tin (GeSn), or germanium (Ge). Polycrystalline or amorphous surfaces may include dielectric materials, such as oxides, oxynitrides, oxycarbides, oxycarbide nitrides, nitrides, or mixtures thereof.

The reaction chamber utilized for the deposition may be an atomic layer deposition reaction chamber, or a chemical vapor deposition reaction chamber, or any of the reaction chambers as previously described herein. In some embodiments of the disclosure, the substrate may be heated to a desired deposition temperature for the subsequent cyclical deposition phase 105. For example, the substrate may be heated to a substrate temperature of less than approximately 800° C., or less than approximately 700° C., or less than approximately 600° C., or less than approximately 500° C., or less than approximately 400° C., or less than approximately 300° C., or even less than approximately 200° C. In some embodiments of the disclosure, the substrate temperature during the exemplary atomic layer deposition process 100 may be between 200° C. and 800° C., or between 400° C. and 700° C., or between 500° C. and 600° C.

In addition, to achieving a desired deposition temperature, i.e., a desired substrate temperature, the exemplary atomic layer deposition process 100 may also regulate the pressure within the reaction chamber during deposition to obtain desirable characteristics of the deposited molybdenum metal film and achieve direct deposition of the molybdenum metal film on a dielectric surface. For example, in some embodiments of the disclosure, the exemplary atomic layer deposition process 100 may be performed within a reaction chamber regulated to a reaction chamber pressure of less than 300 Torr, or less than 200 Torr, or less than 100 Torr, or less than 50 Torr, or less than 30 Torr, or even less than 10 Torr. In some embodiments, the pressure within the reaction chamber during deposition may be regulated at a pressure between 10 Torr and 300 Torr, or between 30 Torr and 80 Torr, or even equal to or greater than 30 Torr.

Upon heating the substrate to a desired deposition temperature and regulating the pressure within the reaction chamber, the exemplary atomic layer deposition process 100 may continue with a cyclical deposition phase 105 by means of a process block 120, which comprises contacting the substrate with a first vapor phase reactant and particularly, in some embodiments, contacting the substrate with a first vapor phase reactant comprising a molybdenum halide precursor, i.e., the molybdenum precursor.

In some embodiments of the disclosure, the molybdenum halide precursor may comprise a molybdenum chloride precursor, a molybdenum iodide precursor, or a molybdenum bromide precursor. For example, as a non-limiting example, the first vapor phase reactant may comprise a molybdenum chloride, such as, for example, molybdenum pentachloride (MoCl₅).

In some embodiments, the molybdenum halide precursor may comprise a molybdenum chalcogenide and in particular embodiments the molybdenum halide precursor may comprise a molybdenum chalcogenide halide. For example, the molybdenum chalcogenide halide precursor may comprise a molybdenum oxyhalide selected from the group comprising: a molybdenum oxychloride, a molybdenum oxyiodide, or a molybdenum oxybromide. In particular embodiments of the disclosure, the molybdenum precursor may comprise a molybdenum oxychloride, including, but not limited to, molybdenum (IV) dichloride dioxide (MoO₂Cl₂).

In some embodiments of the disclosure, contacting the substrate with a first vapor phase reactant comprising a molybdenum halide precursor may comprise contacting the molybdenum halide precursor to the substrate for a time period of between about 0.1 seconds and about 60 seconds, between about 0.1 seconds and about 10 seconds, or between about 0.5 seconds and about 5.0 seconds. In addition, during the contacting of the substrate with the molybdenum halide precursor, the flow rate of the molybdenum halide precursor may be less than 1000 sccm, or less than 500 sccm, or less than 100 sccm, or less than 10 sccm, or even less than 1 sccm. In addition, during the contacting of substrate with the molybdenum halide precursor the flow rate of the molybdenum precursor may range from about 1 to 2000 sccm, from about 5 to 1000 sccm, or from about 10 to about 500 sccm.

The exemplary atomic layer deposition process for deposition a molybdenum metal film directly on a dielectric surface as illustrated by process 100 of FIG. 1 may continue by purging the reaction chamber. For example, excess first vapor phase reactant and reaction byproducts (if any) may be removed from the surface of the substrate, e.g., by pumping with an inert gas. In some embodiments of the disclosure, the purge process may comprise a purge cycle wherein the substrate surface is purged for a time period of less than approximately 5.0 seconds, or less than approximately 3.0 seconds, or even less than approximately 2.0 seconds. Excess first vapor phase reactant, such as, for example, excess molybdenum precursor and any possible reaction byproducts may be removed with the aid of a vacuum, generated by a pumping system in fluid communication with the reaction chamber.

Upon purging the reaction chamber with a purge cycle the exemplary atomic layer deposition process 100 may continue with a second stage of the cyclical deposition phase 105 by means of a process block 130 which comprises contacting the substrate with a second vapor phase reactant, and particularly contacting the substrate with a second vapor phase reactant comprising a reducing agent precursor (“the reducing precursor”).

In some embodiments of the disclosure, the reducing agent precursor may comprise at least one of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, an alcohol, an aldehyde, a carboxylic acid, a borane, or an amine. In further embodiments, the reducing agent precursor may comprise at least one of silane (SiH₄), disilane (Si₂H₆), trisilane (Si₃H₈), germane (GeH₄), digermane (Ge₂H₆), borane (BH₃), or diborane (B₂H₆). In particular embodiments of the disclosure, the reducing agent precursor may comprise molecular hydrogen (H₂).

In some embodiments of the disclosure, contacting the substrate with the reducing agent precursor may comprise contacting the substrate with the reducing agent precursor for a time period of between about 0.01 seconds and about 180 seconds, between about 0.05 seconds and about 60 seconds, or between about 0.1 seconds and about 10.0 seconds. In addition, during the contacting of the substrate with the reducing agent precursor substrate, the flow rate of the reducing agent precursor may be less than 30 slm, or less than 15 slm, or less than 10 slm, or less than 5 slm, or less than 1 slm, or even less than 0.1 slm. In addition, during the contacting of the substrate with the reducing agent precursor to the substrate the flow rate of the reducing agent precursor may range from about 0.1 to 30 slm, from about 5 to 15 slm, or equal to or greater than 10 slm.

Upon contacting the substrate with the reducing agent precursor, the exemplary process 100 for depositing a molybdenum metal film directly on a dielectric surface may proceed by purging the reaction chamber. For example, excess reducing agent precursor and reaction byproducts (if any) may be removed from the surface of the substrate, e.g., by pumping whilst flowing an inert gas. In some embodiments of the disclosure, the purge process may comprise purging the substrate surface for a time period of between approximately 0.1 seconds and approximately 30 seconds, or between approximately 0.5 seconds and approximately 3 seconds, or even between approximately 1 second and 2 seconds.

Upon completion of the purge of the second vapor phase reactant, i.e., the reducing agent precursor (and any reaction byproducts) from the reaction chamber, the cyclic deposition phase 105 of exemplary atomic layer deposition process 100 may continue with a decision gate 140, wherein the decision gate 140 is dependent on the thickness of the molybdenum metal film deposited. For example, if the molybdenum metal film is deposited at an insufficient thickness for a desired device application, then the cyclical deposition phase 105 may be repeated by returning to the process block 120 and continuing through a further deposition cycle, wherein a unit deposition cycle may comprise contacting the substrate with a molybdenum halide precursor (process block 120), purging the reaction chamber, contacting the substrate with a reducing agent precursor (process block 130), and again purging the reaction chamber. A unit deposition cycle of cyclical deposition phase 105 may be repeated one or more times until a desired thickness of a molybdenum metal film is deposited over the substrate and particularly directly on a dielectric surface. Once the molybdenum metal film has been deposited to the desired thickness, the exemplary atomic layer deposition process 100 may exit via a process block 150 and the substrate comprising a dielectric surface, with the molybdenum metal film deposited thereon, may be subjected to further processing for the formation of a device structure.

It should be appreciated that in some embodiments of the disclosure, the order of contacting of the substrate with the first vapor phase reactant (e.g., the molybdenum precursor) and the second vapor phase reactant (e.g., the reducing precursor) may be such that the substrate is first contacted with the second vapor phase reactant followed by the first vapor phase reactant. In addition, in some embodiments, the cyclical deposition phase 105 of exemplary process 100 may comprise contacting the substrate with the first vapor phase reactant one or more times prior to contacting the substrate with the second vapor phase reactant one or more times. In addition, in some embodiments, the cyclical deposition phase 105 of exemplary process 100 may comprise contacting the substrate with the second vapor phase reactant one or more times prior to contacting the substrate with the first vapor phase reactant one or more times.

In some embodiments the cyclical deposition process may be a hybrid ALD/CVD or a cyclical CVD process. For example, in some embodiments, the growth rate of the ALD process may be low compared with a CVD process. One approach to increase the growth rate may be that of operating at a higher substrate temperature than that typically employed in an ALD process, resulting in some portion of a chemical vapor deposition process, but still taking advantage of the sequential introduction of precursors, such a process may be referred to as cyclical CVD. In some embodiments, a cyclical CVD process may comprise the introduction of two or more precursors into the reaction chamber wherein there may be a time period of overlap between the two or more precursors in the reaction chamber resulting in both an ALD component of the deposition and a CVD component of the deposition. For example, a cyclical CVD process may comprise the continuous flow of a one precursor and the periodic pulsing of a second precursor into the reaction chamber.

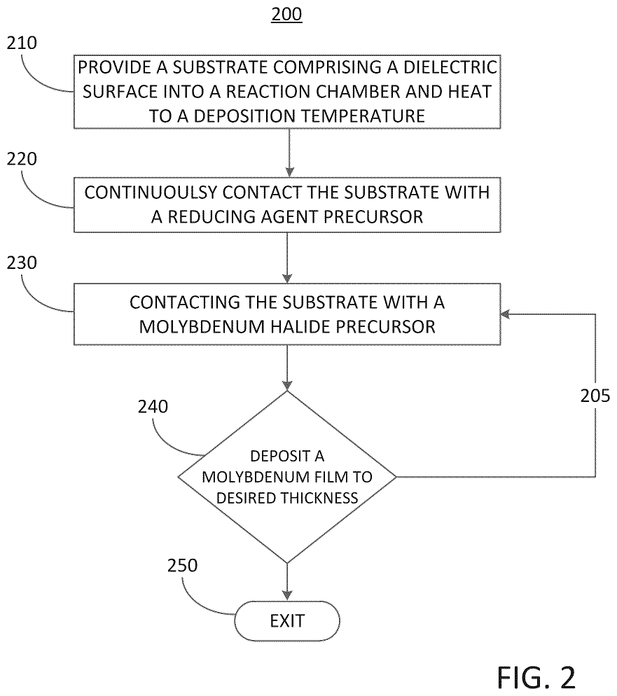

Therefore, in alternative embodiments of the disclosure, a molybdenum metal film may be deposited directly on a dielectric material surface employing a cyclical chemical vapor deposition (CCVD) process. An exemplary cyclical chemical vapor deposition process 200 for depositing a molybdenum metal film directly on a dielectric surface is illustrates with reference to FIG. 2. It should be noted that the cyclical deposition process 200 comprises certain process blocks which are equivalent, or substantially equivalent, to certain process blocks of exemplary atomic layer deposition process 100 of FIG. 1, therefore equivalent process blocks are summarized in brief and the additional/modified process blocks are described in greater detail.

In more detail, the exemplary cyclical chemical vapor deposition process 200 may commence with a process block 210 comprising providing a substrate comprising a dielectric surface into a reaction chamber and heating the substrate to a deposition temperature. The process block 110 has been described in detail with reference process block 110 of FIG. 1 and therefore the details of the process block 210 are not repeated with respect to the cyclical chemical vapor deposition process 200.

Upon heating the substrate to the desired deposition temperature and regulating the reaction chamber pressure, the cyclical chemical vapor deposition process 200 may continue with a process block 220 comprising continuously contacting the substrate with a reducing agent precursor. In more detail, the reducing agent precursor may be introduced into the reaction chamber and contact the substrate disposed in reaction chamber at a flow rate of less than 30 slm, or less than 15 slm, or less than 10 slm, or less than 5 slm, or less than 1 slm, or even less than 0.1 slm. In some embodiments, during the contacting of the substrate with the reducing agent precursor the flow rate of the reducing agent precursor may range from about 0.1 to 30 slm, from about 5 to 15 slm, or equal to or greater than 10 slm. The reducing agent precursor may comprise any one or more of the reducing agent precursors described in detail with reference to the process block 130 of exemplary atomic layer deposition process 100.

The exemplary cyclical chemical vapor deposition process 200 may continue by performing a cyclical deposition phase 205 by means of a process block 230 comprising contacting the substrate with a molybdenum halide precursor. As opposed to the exemplary atomic layer deposition process 100, in the cyclical chemical vapor deposition process 200 the molybdenum halide precursor and the reducing agent precursor are present concurrently within the reaction chamber and therefore concurrently both the molybdenum halide precursor and the reducing agent precursor contact the substrate and particularly contact a dielectric surface of the substrate. In other words, the process block 230 comprises co-flowing both the molybdenum halide precursor and the reducing agent precursor into the reaction chamber and contacting the substrate with a gas mixture comprising at least the molybdenum halide precursor and the reducing agent precursor. The molybdenum halide precursor may comprise any one or more of the molybdenum halide precursors described in detail with reference to the process block 120 of exemplary atomic layer deposition process 100.

In some embodiments of the disclosure, contacting the substrate with the molybdenum halide precursor (i.e., process block 230) may comprise contacting the molybdenum halide precursor to the substrate for a time period of between about 0.1 seconds and about 60 seconds, between about 0.1 seconds and about 10 seconds, or between about 0.5 seconds and about 5.0 seconds. In addition, during the contacting of the substrate with the molybdenum halide precursor, the flow rate of the molybdenum halide precursor may be less than 1000 sccm, or less than 500 sccm, or less than 100 sccm, or less than 10 sccm, or even less than 1 sccm. In addition, during the contacting of substrate with the molybdenum halide precursor the flow rate of the molybdenum precursor may range from about 1 to 2000 sccm, from about 5 to 1000 sccm, or from about 10 to about 500 sccm.

Whilst maintaining the flow of the reducing agent precursor the cyclic deposition phase 205 of exemplary cyclical chemical vapor deposition process 200 may continue with a decision gate 240, wherein the decision gate 240 is dependent on the thickness of the molybdenum metal film deposited. For example, if the molybdenum metal film is deposited at an insufficient thickness for a desired device application, then the cyclical deposition phase 205 may be repeated by returning to the process block 230 and introducing a further pulse of the molybdenum halide precursor into the reaction chamber. The exemplary cyclical chemical vapor deposition process 200 therefore comprises continuously flow the reducing agent precursor and periodically introducing the molybdenum halide into the reaction chamber to thereby deposit a molybdenum metal film directly on a surface of a dielectric material. Once the molybdenum metal film has been deposited to the desired thickness, the exemplary cyclical chemical vapor deposition process 200 may exit via a process block 250 and the substrate comprising a dielectric surface, with the molybdenum metal film deposited directly thereon, may be subjected to further processing for the formation of a device structure.

In alternative embodiments of the disclosure, an exemplary cyclical chemical vapor deposition process may comprise continuously flowing the molybdenum halide precursor and periodically introducing the reducing agent precursor into the reaction chamber to thereby deposit a molybdenum metal film directly on a surface of a dielectric material.

The exemplary deposition processes disclosure herein may deposit a molybdenum metal film directly on a dielectric surface at a growth rate from about 0.05 Å/cycle to about 10 Å/cycle, from about 0.5 Å/cycle to about 5 Å/cycle, or even from about 1 Å/cycle to about 2 Å/cycle. In some embodiments the growth rate of the molybdenum metal film directly on a dielectric surface is more than about 0.5 Å/cycle, more than about 1 Å/cycle, or even more than about 2 Å/cycle. In some embodiments of the disclosure, the molybdenum metal film may be deposited at a growth rate of approximately 1 Å/cycle.

The molybdenum metal films deposited by the methods disclosed herein may be continuous films. In some embodiments, the molybdenum metal film may be continuous at a thickness below approximately 100 Angstroms, or below approximately 60 Angstroms, or below approximately 50 Angstroms, or below approximately 40 Angstroms, or below approximately 30 Angstroms, or below approximately 20 Angstroms, or below approximately 10 Angstroms, or even below approximately 5 Angstroms. The continuity referred to herein can be physical continuity or electrical continuity. In some embodiments of the disclosure the thickness at which a material film may be physically continuous may not be the same as the thickness at which a film is electrically continuous, and vice versa.

In some embodiments of the disclosure, the molybdenum metal films formed may have a thickness from about 20 Angstroms to about 250 Angstroms, or about 50 Angstroms to about 200 Angstroms, or even about 100 Angstroms to about 150 Angstroms. In some embodiments, the molybdenum metal films deposited according to some of the embodiments described herein may have a thickness greater than about 20 Angstroms, or greater than about 30 Angstroms, or greater than about 40 Angstroms, or greater than about 50 Angstroms, or greater than about 60 Angstroms, or greater than about 100 Angstroms, or greater than about 250 Angstroms, or greater than about 500 Angstroms, or greater. In some embodiments the molybdenum metal films deposited according to some of the embodiments described herein may have a thickness of less than about 250 Angstroms, or less than about 100 Angstroms, or less than about 50 Angstroms, or less than about 25 Angstroms, or less than about 10 Angstroms, or even less than about 5 Angstroms. In some embodiments, the molybdenum metal film disposed directly on a dielectric surface may have a thickness between approximately 100 Angstroms and 250 Angstroms.

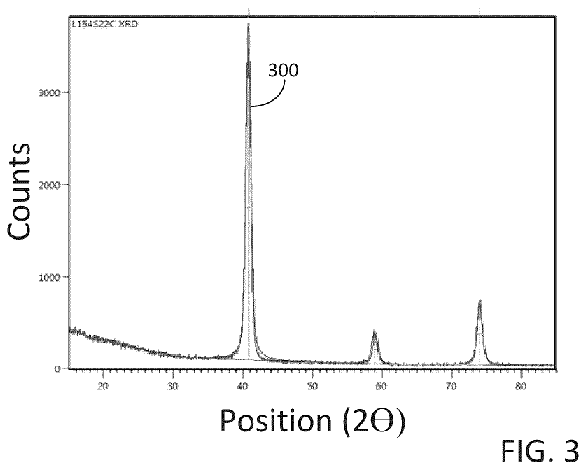

In some embodiments of the disclosure, the molybdenum metal film may be deposited directly on a dielectric surface such that the molybdenum metal film may comprise a crystalline film. For example, FIG. 3 illustrates x-ray diffraction (XRD) data obtained from a 150 Angstrom thick molybdenum metal film deposited directly on an aluminum oxide (Al₂O₃) surface. Examination of the XRD data of FIG. 3 clearly indicates the crystalline nature of the molybdenum metal film as indicated by the XRD peak labelled as 300. In some embodiments, the molybdenum metal film may comprise a single crystalline film. In some embodiments, the molybdenum metal film may comprise a polycrystalline film wherein the plurality of crystalline grains comprising the polycrystalline molybdenum metal film may have a grain size greater than 100 Angstroms, or greater than 200 Angstroms, or even greater than 250 Angstroms. In some embodiments, the molybdenum metal film may comprise a body centered cubic crystalline structure.

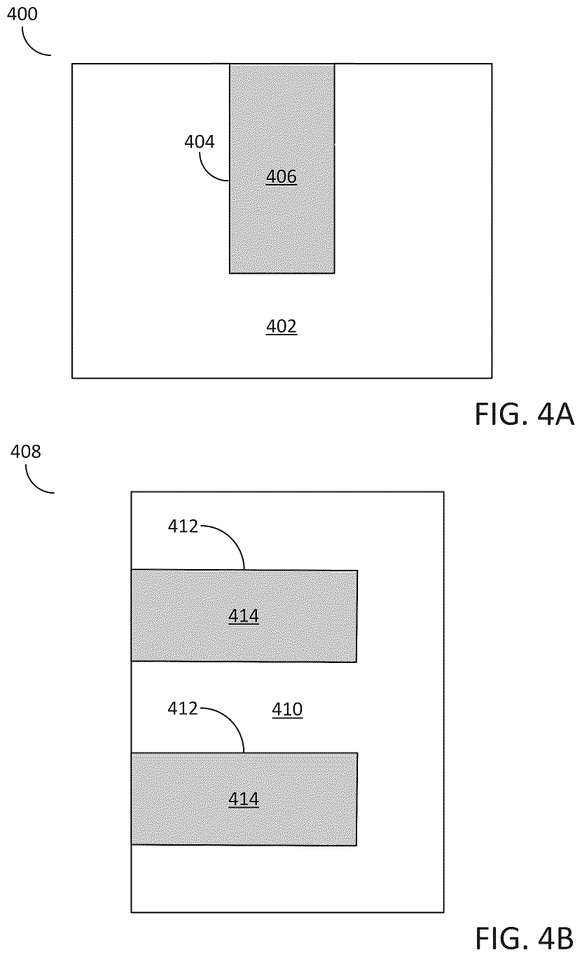

In some embodiments of the disclosure, the molybdenum metal film may be deposited on a dielectric surface with one or more high aspect ratio gap features, including vertical gap features and/or horizontal gap features. For example, FIG. 4A illustrates a semiconductor device structure 400 which comprises a dielectric material 402 with a vertical high aspect ratio gap feature 404, wherein the aspect ratio (height:width) may be greater than 2:1, or greater than 5:1, or greater than 10:1, or greater than 25:1, or greater than 50:1, or even greater than 100:1, wherein “greater than” as used in this example refers to a greater distance in the height of the gap feature. The deposition methods disclosure herein may be utilized to deposit a molybdenum metal film directly over the surface of the vertical high aspect ratio gap feature 404, as illustrated by a molybdenum metal film 406. In some embodiments, the step coverage of the molybdenum metal film directly on the vertical high aspect ratio dielectric gap feature may be equal to or greater than about 50%, or greater than about 80%, or greater than about 90%, or greater than about 95%, or greater than about 98%, or about 99% or greater.

As a non-limiting example, the semiconductor device structure 400 may represent a partially fabricated CMOS logic device wherein the dielectric material 402 may comprise an interlayer dielectric and the molybdenum metal film 406 may comprise a metal gap-fill for providing electrical connection to one or more transistor structures (not shown). As illustrated in FIG. 4A, the molybdenum metal film 406 is in direct contact with the dielectric material 402 without the need for an intermediate barrier layer material, thereby reducing the overall effective electrical resistivity of the semiconductor device structure 400.

In some embodiments, the molybdenum metal film may be utilized as a gap-fill metallization and the molybdenum metal film may fill the gap features, i.e., a vertical high aspect ratio gap feature, without the formation of a seam, wherein a seam may refer to a line or one or more voids formed by the abutment of edges formed in a gap fill material, and the seam can be confirmed by using scanning transmission electron microscopy (STEM) or transmission electron microscopy (TEM), wherein if observations reveal a clear vertical line or one or more vertical voids in the gap fill material, a seam is present.

As a further non-limiting example, FIG. 4B illustrates a semiconductor device structure 408 which comprises a dielectric material 410 with one or more horizontal high aspect ratio gap feature 412, wherein the aspect ratio (height:width) may be greater than 1:2, or greater than 1:5, or greater than 1:10, or greater than 1:25, or greater than 1:50, or even greater than 1:100, wherein “greater than” as used in this example refers to a greater distance in the width of the gap feature. The deposition methods disclosure herein may be utilized to deposit a molybdenum metal film directly over the surface of the horizontal high aspect ratio gap feature 412, as illustrated by a molybdenum metal film 414. In some embodiments, the step coverage of the molybdenum metal film directly on the horizontal high aspect ratio dielectric feature may be equal to or greater than about 50%, or greater than about 80%, or greater than about 90%, or greater than about 95%, or greater than about 98%, or about 99% or greater.

As a non-limiting example embodiment, the semiconductor device structure 408 may represent a portion of a partially fabricated memory device wherein the dielectric material 402 may comprise an aluminum oxide (Al₂O₃) and the molybdenum metal film 406 may comprise a metal gate structure.

As with the vertical gap-fill processes, the molybdenum metal film may be utilized as a gap-fill metallization for horizontal high aspect ratio features without the formation of a seam, as previously described.

In some embodiments of the disclosure, the molybdenum metal films deposited directly on a dielectric surface may comprise low electrical resistivity molybdenum metal films. For example, in some embodiments, the molybdenum metal films may have an electrical resistivity of less than 3000μΩ-cm, or less than 1000μΩ-cm, or less than 500μΩ-cm, or less than 200μΩ-cm, or less than 100μΩ-cm, or less than 50μΩ-cm, or less than 25μΩ-cm, or less than 15μΩ-cm, or even less than 10 μΩ-cm. As a non-limiting example, a molybdenum metal film may be deposited directly over a surface of a dielectric material to a thickness of approximately less than 100 Angstroms and the molybdenum metal film may exhibit an electrical resistivity of less than 35 μΩ-cm. As a further non-limiting example, a molybdenum metal film may be deposited directly over a surface of a dielectric material to a thickness of less than 200 Angstroms and the molybdenum metal film may exhibit an electrical resistivity of less than 25 μΩ-cm.

In some embodiments of the disclosure, the methods of depositing a molybdenum metal film directly on a dielectric surface may further comprise depositing a molybdenum metal film with a low atomic percentage (atomic-%) of impurities. For example, the molybdenum metal films of the current disclosure may comprise an impurity concentration of less than 5 atomic-%, or less than 2 atomic-%, or even less than 1 atomic-%. In some embodiments, the impurities disposed within the molybdenum metal film may comprise at least oxygen and chlorine.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for depositing a molybdenum metal film directly on a dielectric material surface of a substrate by a cyclical deposition process, the method comprising:
providing the substrate comprising the dielectric material surface into a reaction chamber; and
depositing the molybdenum metal film directly on the dielectric material surface using a plurality of deposition cycles, wherein each deposition cycle comprises:
contacting the substrate in the reaction chamber with a pulse of a first vapor phase reactant comprising a molybdenum halide precursor selected from the group consisting of molybdenum pentachloride (MoCl₅), molybdenum iodide, molybdenum bromide, and a molybdenum chalcogenide halide; and
contacting the substrate in the reaction chamber with a second vapor phase reactant comprising a reducing agent precursor;
wherein the second vapor phase reactant is continuously contacting the substrate through the plurality of deposition cycles.

2. The method of claim 1, further comprising depositing the molybdenum metal film directly on the dielectric material surface until the molybdenum metal film comprises a thickness of about 50 Angstroms to about 200 Angstroms.

3. The method of claim 1, further comprising heating the substrate to a substrate temperature between 500° C. and 600° C.

4. The method of claim 1, wherein the reducing agent precursor comprises at least one of a silane, a forming gas (H₂+N₂), an alkyl-hydrazine, an alcohol, an aldehyde, and a carboxylic acid.

5. The method of claim 4, wherein the steps of contacting the substrate in the reaction chamber with the first vapor phase reactant and contacting the substrate in the reaction chamber with the second vapor phase reactant are immediately sequential with no other intervening steps.

6. The method of claim 1, wherein the molybdenum chalcogenide halide comprises molybdenum (IV) dichloride dioxide (MoO₂Cl₂).

7. The method of claim 1, wherein the substrate comprises one or more high aspect ratio gaps.

8. The method of claim 1, wherein the steps of contacting the substrate in the reaction chamber with the first vapor phase reactant and contacting the substrate in the reaction chamber with the second vapor phase reactant are immediately sequential with no other intervening steps.

9. A method for depositing a molybdenum metal film directly on a dielectric material surface of a substrate by a cyclical deposition process, the method comprising:
providing the substrate comprising the dielectric material surface into a reaction chamber; and
depositing the molybdenum metal film directly on the dielectric material surface using a plurality of deposition cycles, wherein the each deposition cycle comprises:
contacting the substrate with a pulse of a first vapor phase reactant comprising a molybdenum oxyhalide; and
contacting the substrate with a second vapor phase reactant;
wherein the second vapor phase reactant is continuously contacting the substrate through the plurality of deposition cycles.

10. The method of claim 9, further comprising depositing the molybdenum metal film directly on the dielectric material surface until the molybdenum metal film comprises a thickness of about 50 Angstroms to about 200 Angstroms

11. The method of claim 9, further comprising heating the substrate to a substrate temperature between 500° C. and 600° C.

12. The method of claim 9, wherein the second vapor phase reactant comprises at least one of a silane, a reducing agent precursor comprising at least one of forming gas (H₂+N₂), an alkyl-hydrazine, an alcohol, an aldehyde, and a carboxylic acid

13. The method of claim 9, wherein the substrate comprises one or more high aspect ratio gaps.

14. The method of claim 9, wherein the dielectric material surface comprises at least one of aluminum oxide (Al₂O₃), silicon oxynitride (SiON), silicon oxycarbide nitride (SiOCN), or silicon carbon nitride (SiCN).

15. The method of claim 9, wherein the steps of contacting the substrate in the reaction chamber with the first vapor phase reactant and contacting the substrate in the reaction chamber with the second vapor phase reactant are immediately sequential with no other intervening steps.

16. A method for depositing a molybdenum metal film directly on a dielectric material surface of a substrate by a cyclical deposition process, the method comprising:
providing the substrate comprising the dielectric material surface into a reaction chamber, wherein the substrate comprises one or more horizontal gaps; and
depositing the molybdenum metal film directly on the dielectric material surface using a plurality of deposition cycles, wherein the each deposition cycle comprises:
contacting the substrate with a pulse of a first vapor phase reactant comprising a molybdenum halide; and
contacting the substrate with a second vapor phase reactant comprising a reducing agent precursor comprising at least one of forming gas (H₂+N₂), an alkyl-hydrazine, an alcohol, an aldehyde, and a carboxylic acid;
wherein the second vapor phase reactant is continuously contacting the substrate through the plurality of deposition cycles.

17. The method of claim 16, wherein the dielectric material surface comprises aluminum oxide (Al₂O₃).

18. The method of claim 16, wherein the molybdenum metal film is a crystalline film.

19. The method of claim 18, wherein the crystalline film has a plurality of crystalline grains with a grain size of greater than 100 Angstroms.

20. The method of claim 19, wherein the molybdenum metal film has an impurity concentration less than 2 atomic-%.
